(19) United States
(12) Patent Application Publication
(10) Pub. No.: US 2009/0243085 A1
(43) Pub. Date: Oct. 1, 2009

(54) APPARATUS AND METHOD FOR ATTACHING A HEAT DISSIPATING DEVICE

(76) Inventor: Sabina J. Houle, Phoenix, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/059,931

(22) Filed: Mar. 31, 2008

(51) Int. Cl. H01L 23/36; H01L 21/60

(52) U.S. Cl. 257/712; 438/122; 257/E23.101; 257/E21.506

(57) ABSTRACT

A microelectronic package is provided. The microelectronic package includes a heat dissipating device having a top side and a bottom side and a thermal interface material disposed adjacent to the bottom side of the heat dissipating device. The microelectronic package also includes a patterned metal layer comprising at least two metals disposed on the bottom side of the heat dissipating device, wherein the patterned metal layer is to adhere the heat dissipating device to the thermal interface material.

### FIELD

The disclosed embodiments relate generally to semiconductor manufacturing technology and, more particularly to, attaching a heat dissipating device to a thermal interface material.

### BACKGROUND

With recent advancements in the semiconductor manufacturing technology microelectronic components are becoming smaller and circuitry within such components is becoming increasingly dense. As the circuit density increases, heat generation from such components also increases. Various techniques are employed to dissipate the heat generated from the components. For example, a heat dissipating device such as an integrated heat spreader may be employed to dissipate the generated heat to the surrounding environment. Typically, a thermally conductive material such as a thermal interface material (TIM) is employed to thermally couple the heat dissipating device to a semiconductor die.

One challenge is thermal degradation of the thermal interface material due to delamination of the thermal interface material from the heat dissipating device. Further, current manufacturing techniques require different processes for attaching the heat dissipating device to the thermal interface material, based on the type of the thermal interface material. This leads to more costly and/or less effective attachment techniques for attachment of the heat dissipating device to the thermal interface material.

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 illustrates an embodiment of a microelectronic package;

FIG. 2 illustrates an exemplary pattern of the patterned metal layer of FIG. 1;

FIG. 3 illustrates another exemplary pattern of the patterned metal layer of FIG. 1;

FIG. 4 illustrates another exemplary pattern of the patterned metal layer of FIG. 1;

FIG. 5 illustrates another exemplary pattern of the patterned metal layer of FIG. 1;

FIG. 6 illustrates an exemplary process for manufacturing the microelectronic package of FIG. 1; and

FIG. 7 illustrates an embodiment of a computer system.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined only as set forth in the accompanying claims.

### DETAILED DESCRIPTION

As discussed in detail below, the embodiments of the present invention function to provide a microelectronic package with a structure to improve adhesion between a thermal interface material and a heat dissipating device of the package.

References in the specification to “one embodiment”, “an embodiment”, “an exemplary embodiment”, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The following description includes terms, such as top, bottom etc. that are used for descriptive purposes only and are not to be construed as limiting. The embodiments of the device or article described herein can be manufactured or used in a number of positions and orientations.

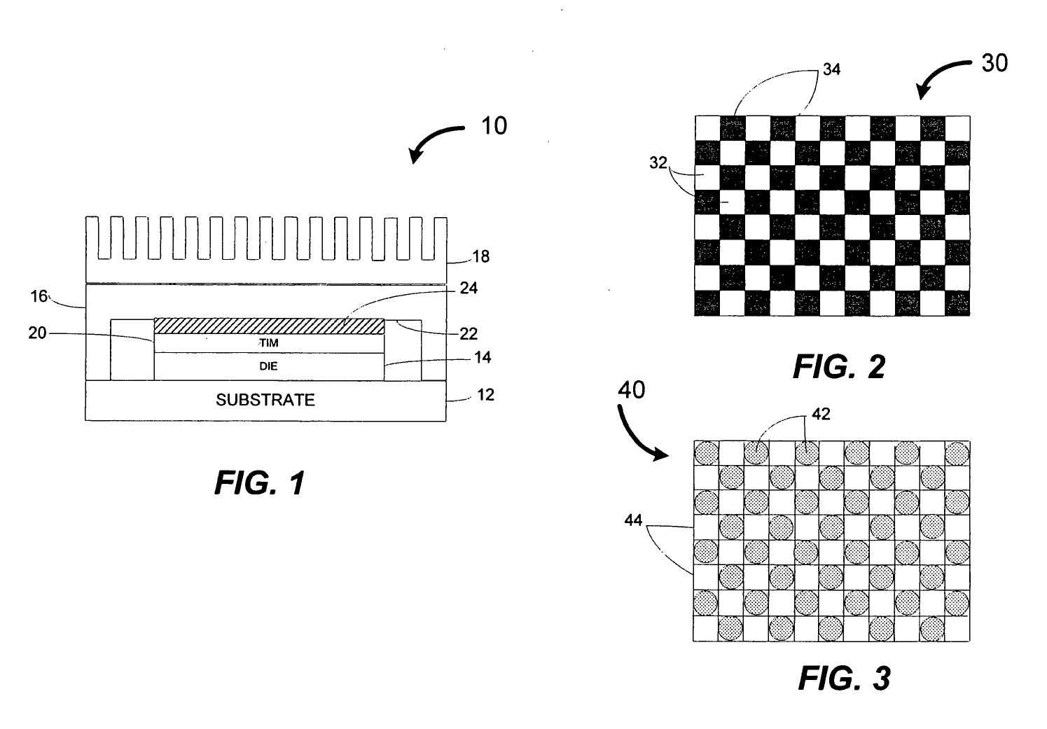

Referring first to FIG. 1, a microelectronic package 10 is illustrated. The microelectronic package 10 includes a substrate 12 and a die 14 coupled to the substrate 12. The substrate 12 may be formed of a variety of materials including ceramic and printed circuit boards. Further, the substrate 12 may be a one-layer board or a multi-layer board. In certain embodiments, the die 14 forms one of a data storage device, a digital signal processor, a micro-controller and a hand-held device. Typically, the die 14 is attached to one side of the substrate 12 and the attachment may be through a plurality of solder balls or solder bump connections (not shown), among other attachment methods.

The microelectronic package 10 includes a heat dissipating device 16 such as an integrated heat spreader (IHS) and a heat sink 18 (e.g., a multi-fin heat sink) for dissipating the heat generated from the microelectronic package 10 to the surrounding environment. The integrated heat spreader 16 may be formed of a suitable conductive material such as copper, aluminum and carbon composites, among others. In the microelectronic package 10, the heat dissipating device 16 is in thermal contact with the die 14 through a thermal interface material (TIM) 20. As illustrated, the thermal interface material 20 is disposed between the die 14 and the heat dissipating device 16 adjacent to a bottom side 22 of the heat dissipating device 16. Examples of the thermal interface material 20 include, but are not limited to, a polymer, a solder and a polymer solder hybrid (PSH).

In operation, heat is typically conducted from the die 14 through the thermal interface material 20 to the heat dissipating device 16 by heat conduction. Further, the heat is transferred from the heat dissipating device 16 to the heat sink 18 and the convective heat transfer primarily transfers the heat from the heat sink 18 to the surrounding environment.

In one embodiment, the microelectronic package 10 includes a patterned metal layer 24 on the bottom side 22 of the heat dissipating device 16. The patterned metal layer 24 may include at least two metals to adhere the heat dissipating device 16 to the thermal interface material 20. Advantageously, the patterned metal layer 24 having the two metals provides a single interface having two or more coating surfaces that would enable the heat dissipating device 16 to adhere to a variety of thermal interface materials such as solder, polymer and polymer solder hybrid. In certain embodiments, a pattern of the metal layer 24 may be selected based upon a material type of the thermal interface material 20. In one embodiment, the pattern of the metal layer 24 is based on material adhesion properties of the thermal interface material 20 and material elongation under strain, modulus and tensile stress. In one embodiment, package stress under TCB and Hast testing indicates that an adhesion failure occurs in corners of a circular pattern of the metal layer 24. In one embodiment, the thickness of the patterned metal layer 24 may be optimized in such regions.

In one embodiment, the thermal interface material 20 includes a polymer solder hybrid and the patterned metal layer 24 may include a nickel plated area and a gold plated area arranged in checkered pattern. In one embodiment, a thickness of the gold plated area is between about 0.5 micrometers to about 10 micrometers. In one embodiment, a thickness of the nickel plated area is between about 0.5 micrometers to about 5 micrometers. The polymer solder hybrid includes a solder filler and a polymer component. In this embodiment, the solder filler of the polymer solder hybrid adheres with the gold plated areas and the polymer component of the polymer solder hybrid adheres with the nickel plated area. In one embodiment, the patterned metal layer 24 may include a combination of a variety of other metals such as copper and silver. Further, based upon a material type and a desired thermal performance of the microelectronic package 10, such metals may be arranged in a variety of patterns. In certain embodiments, a ratio of the at least two metals may be based upon the desired thermal performance of the microelectronic package 10. Exemplary patterns of the patterned metal layer 24 will be described below with reference to FIGS. 2-5.

FIG. 2 illustrates an exemplary pattern 30 of the patterned metal layer 24 of FIG. 1. In one embodiment, the patterned metal layer 30 includes a nickel plated area 32 and a copper plated area 34 arranged in a checkered pattern. In other embodiment, the patterned metal layer 30 may include nickel plated area and gold plated area arranged in a similar checkered pattern. In one embodiment, a ratio of the nickel plated area 32 and the copper plated area 34 may be about 0.5. However, the ratio of the nickel plated area and the copper plated area may vary based upon a desired thermal performance of the microelectronic package 10 (see FIG. 1). In one embodiment, a ratio of nickel plated area in the patterned metal layer 30 may be between about 0.5 to about 0.9. In one embodiment, a ratio of gold plated area in the patterned metal layer 30 may be between about 0.1 to about 0.5. In one embodiment, the nickel plated area 32 and the copper plated area 34 are arranged in a crossing line pattern. In another embodiment, the nickel plated area 32 and the copper plated area 34 are arranged in a dots pattern. However, other patterns may be envisaged.

In the illustrated embodiment, the nickel plated area 32 and the copper plated area 34 form two bonding surfaces to adhere the heat dissipating device 16 (see FIG. 1) to the thermal interface material 20 (see FIG. 1). In one embodiment, the thermal interface material 20 includes polymer solder hybrid. In this exemplary embodiment, the nickel plated area 32 may be optimized to adhere with the polymer component of the polymer solder hybrid and the copper plated area 34 may be optimized to adhere with the solder filler of the polymer solder hybrid. The solder filler of the polymer solder hybrid adheres with the copper plated area 34 through intermetallic coverage (IMC) formation. Further, the polymer component forms an adhesive bond with the nickel plated area 32. As can be seen, both phases (polymer and solder filler) of the polymer solder hybrid have a compatible bonding surface disposed on the heat dissipating device 16 thereby improving the adhesion between the heat dissipating device 16 and the thermal interface material 20 to form a robust microelectronic package 10.

FIG. 3 illustrates another exemplary pattern 40 of the patterned metal layer 24 of FIG. 1. In this embodiment, the patterned metal layer 40 includes gold plated area 42 and a nickel plated area 44 arranged in a circular grid pattern. As described before, the pattern of the metal layer 40 is based upon a failure mode of the structure. In one embodiment, the warpage of the substrate and the IHS coefficient of thermal expansion (CTE) mismatch drive a circular pattern of the metal layer 24. Again, each of the gold plated area 42 and nickel plated area 44 may be optimized to adhere with the solder filler and polymer component of the polymer solder hybrid of the thermal interface material 20 respectively. Further, as described earlier, the ratio of the gold plated area 42 and the nickel plated area 44 may be optimized based upon the desired thermal performance of the microelectronic package.

FIG. 4 illustrates another exemplary pattern 50 of the patterned metal layer 24 of FIG. 1. In this embodiment, the patterned metal layer 50 includes a nickel plated area 52 and a gold plated area 54. The gold plated area 54 may cover a central circular portion 56 as well as a portion 58 adjacent to edges of the patterned metal layer 50. Further, the nickel plated area 52 may form a circular ring 60 between the central circular portion 56 and the portion 58 adjacent to the edges of the patterned metal layer 50. As with the other configurations described above, the nickel plated area 52 covering portion 60 of the patterned metal layer 50 adheres with the polymer component of the polymer solder hybrid. Further, the gold plated area 54 covering portions 56 and 58 adheres with the solder filler of the polymer solder hybrid of the thermal interface material 20. Again, a variety of metals having different ratios in this pattern may be used to form the patterned metal layer 50.

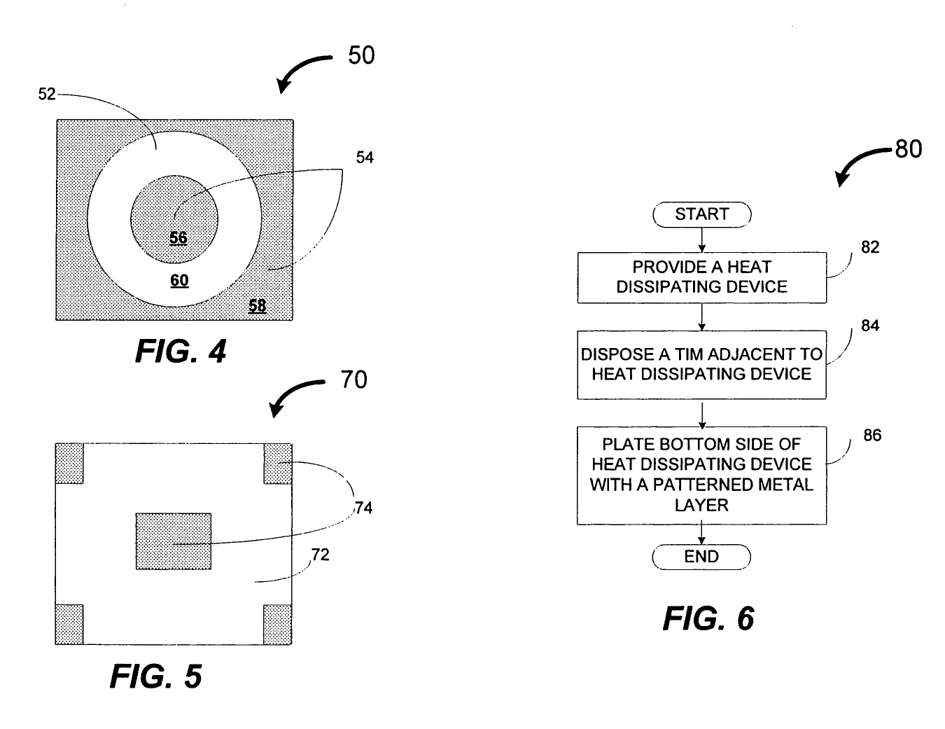

FIG. 5 illustrates another exemplary pattern 70 of the patterned metal layer 24 of FIG. 1. In this embodiment, the patterned metal layer 70 includes a nickel plated area 72 and a gold plated area such as represented by reference numeral 74. As illustrated, the gold plated area 74 covers the corners and a central portion of the patterned metal layer 70. Further, the nickel plated area 72 covers the rest of the area of the patterned metal layer 70. The gold plated area 74 facilitates adhesion of the heat dissipating device 16 (see FIG. 1) to the solder filler of the polymer solder hybrid thermal interface material 20 by forming a bond at the corners and center. Further, the nickel plated area 72 adheres the heat dissipating device 16 to the polymer component of the polymer solder hybrid thermal interface material 20 through intermetallic coverage (IMC). As discussed earlier, a pattern and the metals for the patterned metal layer 70 may be selected based upon the material of the thermal interface material 20 and a desired thermal performance of the microelectronic package 10 (see FIG. 1).

FIG. 6 illustrates a process 80 for manufacturing the microelectronic package 10 of FIG. 1 according to one embodiment. At block 82, a heat dissipating device is provided. The heat dissipating device is coupled to a die of a semiconductor device. Based on the way of assembly of the microelectronic package, the heat dissipating device is attached to a top or bottom surface of the die. In an embodiment, the heat dissipating device includes an integrated heat spreader. Further, a heat sink may be coupled to the integrated heat spreader for dissipating the heat generated from the microelectronic package to the surrounding environment. At block 84, a thermal interface material (TIM) is disposed adjacent to the heat dissipating device. The thermal interface material preferably comprises a polymer, a solder, such as Indium, or a polymer solder hybrid. In certain embodiments, the thermal interface material is disposed by melting a solder perform.

At block 86, a surface of the heat dissipating device adjacent to the thermal interface material is plated with a patterned metal layer. In this embodiment, the patterned metal layer includes at least two metals such as gold, nickel, silver and copper. Further, a pattern of the metal layer is selected based upon the thermal interface material. In certain embodiments, a ratio of the at least two metals in the patterned metal layer is determined based on a desired thermal performance of the microelectronic package. The pattern of the metal layer may be formed using the known patterning techniques such as masking, plasma etching, vapor deposition and electroplating.

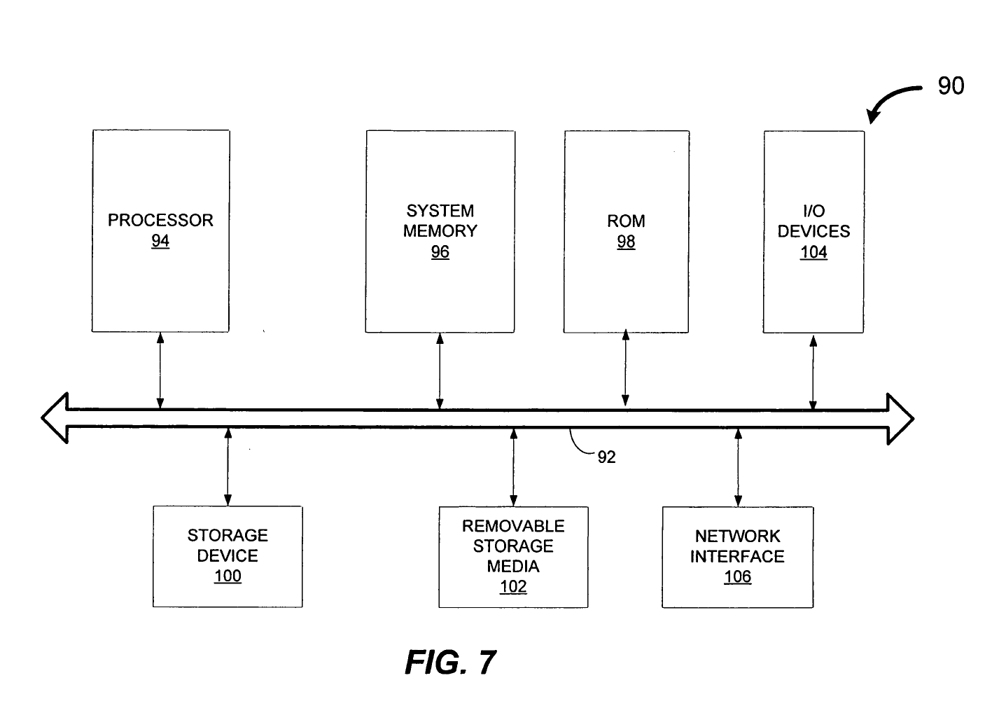

The microelectronic package described above may be disposed in a computer system, a wireless communicator and a hand-held device. FIG. 7 illustrates an embodiment of a computer system 90. The computer system 90 includes a bus 92 to which the various components are coupled. In certain embodiments, the bus 92 includes a collection of a plurality of buses such as a system bus, a Peripheral Component Interface (PCI) bus, a Small Computer System Interface (SCSI) bus, etc. Representation of these buses as a single bus 92 is provided for ease of illustration, and it should be understood that the system 90 is not so limited. Those of ordinary skill in the art will appreciate that the computer system 90 may have any suitable bus architecture and may include any number of combination of buses.

A processor 94 is coupled to the bus 82. The processor 94 may include any suitable processing device or system, including a microprocessor (e.g., a single core or a multi-core processor), a network processor, an application specific integrated circuit (ASIC), or a field programmable gate array (FPGA), or any similar device. It should be noted that although FIG. 7 shows a single processor 94, the computer system 90 may include two or more processors.

The computer system 90 further includes system memory 96 coupled to the bus 92. The system memory 96 may include any suitable type and number of memories, such as static random access memory (SRAM), dynamic random access memory (DRAM), synchronous dynamic random access memory (SDRAM), or double data rate DRAM (DDRDRAM). During operation of the computer system 90, an operating system and other applications may be resident in the system memory 96.

The computer system 90 may further include a read-only memory (ROM) 98 coupled to the bus 92. The ROM 98 may store instructions for the processor 94. The computer system 90 may also include a storage device (or devices) 100 coupled to the bus 92. The storage device 100 includes any suitable non-volatile memory, such as, for example, a hard disk drive. The operating system and other programs may be stored in the storage device 100. Further, a device 102 for accessing removable storage media (e.g., a floppy disk drive or a CD ROM drive) may be coupled to the bus 92.

The computer system 90 may also include one or more Input/Output (I/O) devices 104 coupled to the bus 92. Common input devices include keyboards, pointing devices such as a mouse, as well as other data entry devices. Further, common output devices include video displays, printing devices, and audio output devices. It will be appreciated that these are but a few examples of the types of I/O devices that may be coupled to the computer system 90.

The computer system 90 may further comprise a network interface 106 coupled to the bus 92. The network interface 106 comprises any suitable hardware, software, or combination of hardware and software that is capable of coupling the system 90 with a network (e.g., a network interface card). The network interface 106 may establish a link with the network over any suitable medium (e.g., wireless, copper wire, fiber optic, or a combination thereof) supporting exchange of information via any suitable protocol such as TCP/IP (Transmission Control protocol/Internet Protocol), HTTP (Hyper-Text Transmission Protocol, as well as others.

It should be understood that the computer system 90 illustrated in FIG. 7 is intended to represent an embodiment of such a system and, further, that this system may include any additional components, which have been omitted for clarity and ease of understanding. By way of example, the system 90 may include a direct memory access (DMA) controller, a chip set associated with the processor 84, additional memory (e.g., cache memory) as well as additional signal lines and buses. Also, it should be understood that the computer system 90 may not include all the components shown in FIG. 7. The computer system 90 may comprise any type of computing device, such as a desktop computer, a laptop computer, a server, a hand-held computing device, a wireless communication device, an entertainment system etc.

In this embodiment, the computer system 90 may include the microelectronic package as described in the embodiments above. By way of example, the processor 84 may include a die and a heat dissipating device. Further, a thermal interface material is disposed between the die and the heat dissipating device. A patterned metal layer as described in the embodiments above may be disposed on the heat dissipating device to adhere the heat dissipating device to the thermal interface material.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

1. A microelectronic package, comprising:
a heat dissipating device having a top side and a bottom side;
a thermal interface material disposed adjacent to the bottom side of the heat dissipating device; and
a patterned metal layer comprising at least two metals, wherein the patterned metal layer is disposed on the bottom side of the heat dissipating device and wherein the patterned metal layer is to adhere the heat dissipating device to the thermal interface material.

2. The microelectronic package of claim 1, wherein a pattern of the metal layer is selected based upon a material type of the thermal interface material.

3. The microelectronic package of claim 2, wherein the pattern of the metal layer is based on material adhesion properties of the thermal interface material and material elongation under strain, modulus and tensile stress.

4. The microelectronic package of claim 2, wherein the thermal interface material comprises a polymer solder hybrid and the patterned metal layer comprises a nickel plated area and a gold plated area.

5. The microelectronic package of claim 4, wherein the nickel plated area and the gold plated area are arranged in a checkered grid pattern.

6. The microelectronic package of claim 4, wherein the polymer solder hybrid includes a solder filler to adhere with the gold plated area and wherein the polymer solder hybrid includes a polymer component to adhere with the nickel plated area.

7. The microelectronic package of claim 6, wherein a ratio of the gold plated area and the nickel plated area in the patterned metal layer is based upon a desired thermal performance of the microelectronic package.

8. The microelectronic package of claim 7, wherein the ratio of nickel plated area in the patterned metal layer is between about 0.5 to about 0.9 and wherein a ratio of the gold plated area in the patterned metal layer is between about 0.1 to about 0.5.

9. The microelectronic package of claim 2, wherein the thermal interface material comprises a polymer solder hybrid and the patterned metal layer comprises gold plating in contact regions of the thermal interface material with the heat dissipating device.

10. The microelectronic package of claim 2, wherein the thermal interface material comprises a polymer solder hybrid and the patterned metal layer comprises a nickel plated area and a copper plated area formed in a checkered grid pattern.

11. A method of forming a microelectronic package, comprising:
providing a heat dissipating device having a top side and a bottom side;
disposing a thermal interface material adjacent to the bottom side of the heat dissipating device; and
plating the bottom side of the heat dissipating device with a patterned metal layer comprising at least two metals, wherein the patterned metal layer is to adhere the heat dissipating device to the thermal interface material.

12. The method of claim 11, wherein the thermal interface material comprises a polymer solder hybrid and the at least two metals comprise nickel and gold.

13. The method of claim 11, further comprising:
selecting a pattern of the at least two metals based upon a desired thermal performance of the microelectronic package.

14. The method of claim 13, wherein the pattern comprises a circle grid pattern.

15. A microelectronic package, comprising:
a die;
a heat dissipating device having a top side and a bottom side coupled to the die;
a thermal interface material disposed between the die and the heat dissipating device, wherein the thermal interface material is disposed adjacent to the bottom side of the heat dissipating device; and
a patterned metal layer comprising at least two metals disposed on the bottom side of the heat dissipating device, wherein the patterned metal layer is to adhere the heat dissipating device to the thermal interface material.

16. The microelectronic package of claim 15, wherein a top side of the die is plated with at least two metals to adhere the die to the thermal interface material.

17. The microelectronic package of claim 15, wherein the microelectronic package is disposed in one of a computer, a wireless communicator and a hand-held device.

18. The microelectronic package of claim 15, wherein the die is selected from one of a data storage device, a digital signal processor, a micro-controller and a microprocessor.

19. The microelectronic package of claim 15, wherein the thermal interface material is selected from a polymer thermal interface material, a solder thermal interface material and a polymer solder hybrid thermal interface material.

20. The microelectronic package of claim 19, wherein the patterned metal layer comprises a nickel plated area and a gold plated area.
